(19) United States
(12) Patent Application Publication
(10) Pub. No.: US 2026/0149437 A1
(43) Pub. Date: May 28, 2026

(54) ELECTRONIC APPARATUS

(71) Applicant: Wacom Co., Ltd., Saitama (JP)

(72) Inventor: Yosuke MATSUDA, Saitama (JP)

(73) Assignee: Wacom Co., Ltd., Saitama (JP)

(21) Appl. No.: 19/314,638

(22) Filed: Aug. 29, 2025

(30) Foreign Application Priority Data
Nov. 25, 2024 (JP) 2024-204463

(51) Int. Cl. H03K 5/04

(52) U.S. Cl. CPC H03K 5/04

(57) ABSTRACT

An electronic apparatus includes a primary device that operates according to an I3C communication specification, a secondary device that operates according to an I2C communication specification but is not compliant with the I3C communication specification, a clock bus connected to the primary device and the secondary device, and a blocking device that is connected to the clock bus and blocks, when a clock transmitted from the secondary device toward the clock bus is in a predetermined logic state, input of the clock to the primary device.

### BACKGROUND

### TECHNICAL FIELD

The present disclosure relates to electronic apparatuses, and particularly to electronic apparatuses that perform bus communication.

### DESCRIPTION OF THE RELATED ART

Electronic apparatuses including an inter-integrated circuit (I2C) device that communicates according to a bus communication specification calledI2C and electronic apparatuses including an improved (second) inter-integrated circuit (I3C) device that communicates according to a bus communication specification called I3C, which is an advanced version of I2C, are known in the prior art. The I3C is a communication specification that is generally forward compatible with I2C, but some functions thereof are not compatible.

In this regard, part of the I3C communication specification is disclosed in Sally Huang, “INTRODUCTION TO MIPI I3C,” [online], November 2022, NXP Semiconductors, [searched November 14, 2024], Internet <URL: https://www.nxp.jp/docs/en/training-reference-material/TIP-1109-MIPI-I3C-CN-1.pdf> (hereinafter, referred to as Non Patent Document 1). As described on page 19 of the Non Patent Document 1, I3C does not have a function called clock stretching that is adopted in I2C. The clock stretching is a function that forcibly makes a transition of a logic state of a clock line to a “low state” to put the processing of a primary device on hold when the processing of a secondary device cannot keep up with a clock transmitted from the primary device.

Some I2C devices are not compliant with I3C and cannot disable the clock stretching function. If an I2C device that is not compliant with I3C is connected to a bus that carries out communication with an I3C device, the I2C device will perform clock stretching, resulting in communication failure. Therefore, related-art electronic apparatuses have not been able to communicate in a state where an I2C device that is not compliant with I3C is connected to an I3C device bus.

### BRIEF SUMMARY

The present disclosure has been made in consideration of such a problem, and an object thereof is to provide an electronic apparatus that can communicate in a state where an I2C device that is not compliant with I3C is connected to an I3C device bus.

In order to solve the above problem, an electronic apparatus according to a first aspect of the present disclosure includes a primary device that operates according to an I3C communication specification, a secondary device that operates according to an I2C communication specification but is not compliant with the I3C communication specification, a clock bus connected to the primary device and the secondary device, and a blocking device that is connected to the clock bus and blocks, when a clock transmitted from the secondary device toward the clock bus is in a predetermined logic state, input of the clock to the primary device.

In addition, in the electronic apparatus according to a second aspect of the present disclosure, the blocking device is a diode and has a cathode terminal connected to a clock terminal of the primary device and an anode terminal connected to the clock bus.

In addition, in the electronic apparatus according to a third aspect of the present disclosure, the predetermined logic state includes all logic states, and the blocking device is an input/output circuit provided between the clock bus and the secondary device and is configured to input, to the secondary device, a clock transmitted from the primary device to the blocking device via the clock bus but block input, to the clock bus, of a clock transmitted from the secondary device to the blocking device.

In addition, in the electronic apparatus according to a fourth aspect of the present disclosure, the secondary device performs a clock stretching operation defined in the I2C communication specification and ends the clock stretching operation before a logic state of a clock transmitted from the primary device toward the clock bus becomes a high state.

According to the present disclosure, an electronic apparatus can perform communication in a state where a non-I3C-compliant I2C device is connected to an I3C device bus.

### BRIEF DESCRIPTION OF THE SEVERAL VIEWS OF THE DRAWINGS

FIG. 1 is a diagram illustrating an example of a circuit configuration of an electronic apparatus according to a first embodiment;

FIG. 2 is a timing chart illustrating an example of transitions of logic states of respective signals in the electronic apparatus according to the first embodiment;

FIG. 3 is a diagram illustrating an example of a circuit configuration of an electronic apparatus according to a second embodiment; and

FIG. 4 is a diagram illustrating an example of a circuit configuration of a blocking device according to the second embodiment.

### DETAILED DESCRIPTION

Hereinafter, embodiments of the present disclosure (hereinafter referred to as a “first embodiment” and a “second embodiment”) will be described with reference to the accompanying drawings. In order to facilitate understanding of the description, the same components and steps are denoted by the same reference signs as much as possible in the respective drawings, and duplicated descriptions will be omitted.

### First Embodiment

First, the first embodiment will be described.

### Configuration

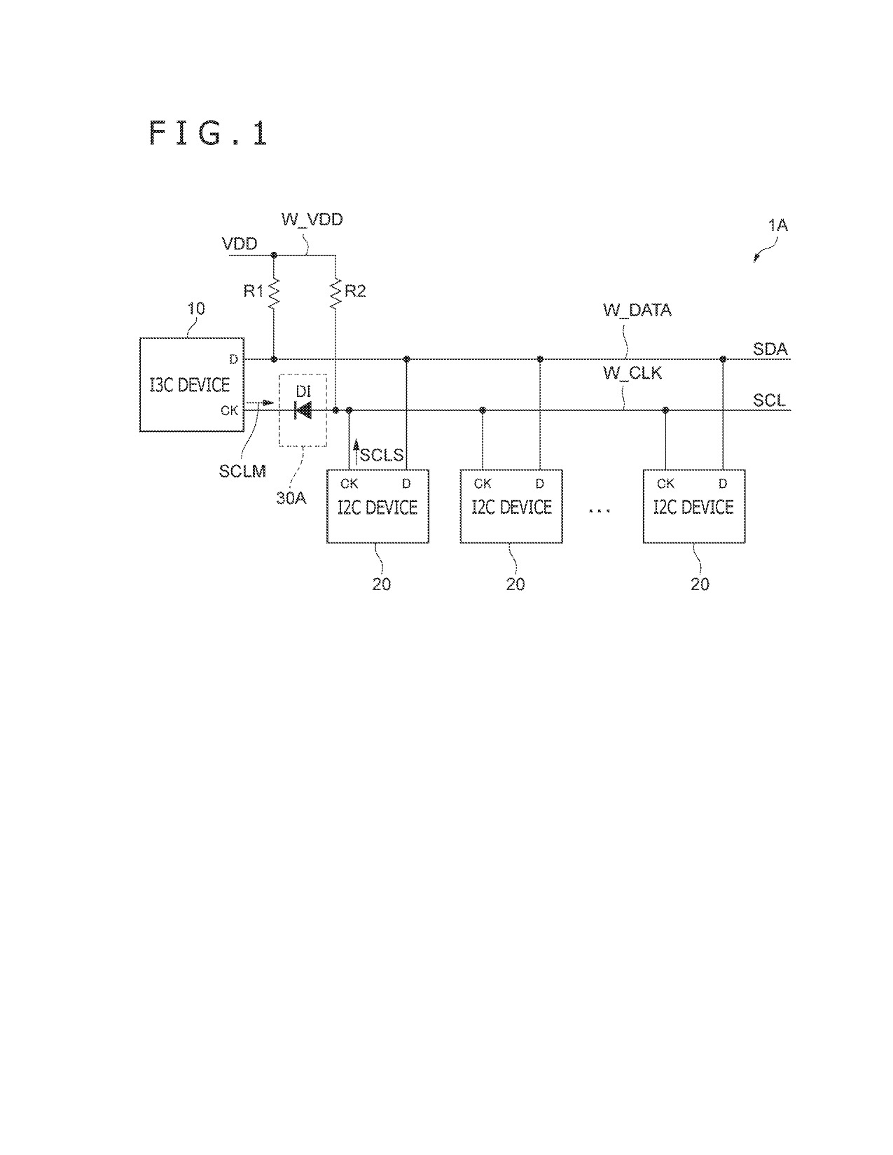

FIG. 1 is a diagram illustrating an example of a circuit configuration of an electronic apparatus 1A according to the first embodiment. As illustrated in FIG. 1, the electronic apparatus 1A includes an I3C device 10, a plurality of I2C devices 20, a blocking device 30A, a data bus W_DATA, a clock bus W_CLK, a power supply line W_VDD, and resistive elements R1 and R2, for example. The electronic apparatus 1A may be, for example, a desktop personal computer, a notebook computer, a tablet, a smartphone, or a mobile phone. Note that the electronic apparatus 1A is not limited to the above examples, and may be any apparatus as long as it includes the above-mentioned components.

The I3C device 10 is a device that operates according to an I3C communication specification. To be specific, the I3C device 10 is an integrated circuit enclosed in an electronic component package, for example, and functions as a primary device in the I3C communication specification. The I3C device 10 has a data terminal D and a clock terminal CK as input/output terminals related to the I3C communication specification. The data terminal D of the I3C device 10 is connected to the data bus W_DATA which is an I3C data bus. Further, the clock terminal CK of the I3C device 10 is connected to the clock bus W_CLK which is an I3C clock bus. The I3C device 10 transmits a data signal SDA as an electrical signal for data conforming to the I3C communication specification, from the data terminal D to the data bus W_DATA. In addition, the I3C device 10 transmits a clock SCLM as an electrical signal for a clock conforming to the I3C communication specification, from the clock terminal CK to the clock bus W_CLK.

Each of the I2C devices 20 is a device that operates according to an I2C communication specification but is not compliant with the I3C communication specification. To be specific, each I2C device 20 is an integrated circuit enclosed in an electronic component package, for example, and functions as a secondary device in the I2C communication specification. Further, each I2C device 20 has a clock stretching function defined in the I2C communication specification, but does not have a function for disabling the clock stretching function. Each I2C device 20 has a data terminal D and a clock terminal CK as input/output terminals related to the I2C communication specification. The data terminal D of each I2C device 20 is connected to the data bus W_DATA. Also, the clock terminal CK of each I2C device 20 is connected to the clock bus W_CLK. The I2C devices 20 receive, at the data terminal D thereof, the data signal SDA transmitted to the data bus W_DATA. In addition, the I2C devices 20 receive, at the clock terminal CK thereof, a clock SCL propagating on the clock bus W_CLK. Moreover, the I2C devices 20 perform a clock stretching operation according to the I2C communication specification. While performing the clock stretching operation, the I2C devices 20 transmit a clock SCLS from the clock terminal CK to the clock bus W_CLK to make the logic state enter a “low state.” Note that, in the electronic apparatus 1A, the plurality of I2C devices 20 are connected to the clock bus W_CLK and the data bus W_DATA, but the arrangement is not limited to this. One I2C device 20 may be connected to the clock bus W_CLK and the data bus W_DATA.

The data bus W_DATA is a data bus that conforms to the I3C communication specification. The data bus W_DATA transmits the data signal SDA from the I3C device 10 to the plurality of I2C devices 20. The data bus W_DATA is connected to the data terminal D of the I3C device 10 and the data terminals D of the plurality of I2C devices 20. Further, the data bus W_DATA is connected to the power supply line W_VDD via the resistive element R1.

The clock bus W_CLK is a clock bus that conforms to the I3C communication specification. The clock bus W_CLK uses the clock SCLM transmitted from the I3C device 10 as the clock SCL and transmits the clock SCL to the plurality of I2C devices 20. Further, the clock bus W_CLK uses the clock SCLS transmitted from the I2C device 20 as the clock SCL and propagates the clock SCL through the clock bus W_CLK. The clock bus W_CLK is connected to the clock terminals CK of the plurality of I2C devices 20. The clock bus W_CLK is also connected to the power supply line W_VDD via the resistive element R2. Moreover, the clock bus W_CLK is connected to the clock terminal CK of the I3C device 10 via the blocking device 30A.

When the clock SCLS transmitted from the I2C device 20 to the clock bus W_CLK is in a predetermined logic state, the blocking device 30A blocks the input of the clock SCLS to the I3C device 10. In the first embodiment, the predetermined logic state is the “low state.” The blocking device 30A is a diode DI or a diode-connected transistor, for example. Here, a case where the blocking device 30A is a diode DI will be described. The blocking device 30A conducts a current flowing from an anode terminal of the blocking device 30A to a cathode terminal thereof but interrupts a current flowing from the cathode terminal to the anode terminal. The blocking device 30A has the cathode terminal connected to the clock terminal CK of the I3C device 10 and the anode terminal connected to the clock bus W_CLK. With this configuration, the blocking device 30A blocks the transmission of the clock SCL to the I3C device 10 when the logic state of the clock SCL propagating on the clock bus W_CLK is in the “low state.” On the other hand, when the logic state of the clock SCL propagating on the clock bus W_CLK is in a “high state,” the blocking device 30A transmits the clock SCL to the I3C device 10.

The resistive elements R1 and R2 are resistors, for example, and both function as pull-up resistors. The resistive element R1 is a pull-up resistor for the data bus W_DATA and connects the power supply line W_VDD and the data bus W_DATA to each other via the resistive element R1. When the logic state of the data signal SDA is neither the “high state” nor the “low state,” the resistive element R1 supplies a power supply potential VDD from the power supply line W_VDD to the data bus W_DATA, thereby making a transition of the logic state of the data signal SDA to the “high state.” The resistive element R2 is a pull-up resistor for the clock bus W_CLK and connects the power supply line W_VDD and the clock bus W_CLK to each other via the resistive element R2. When the logic state of the clock SCL is neither the “high state” nor the “low state,” the resistive element R2 supplies the power supply potential VDD from the power supply line W_VDD to the clock bus W_CLK, thereby making a transition of the logic state of the clock SCL to the “high state.” It should be noted that a logic state that is neither the “high state” nor the “low state” is a “high impedance state,” for example.

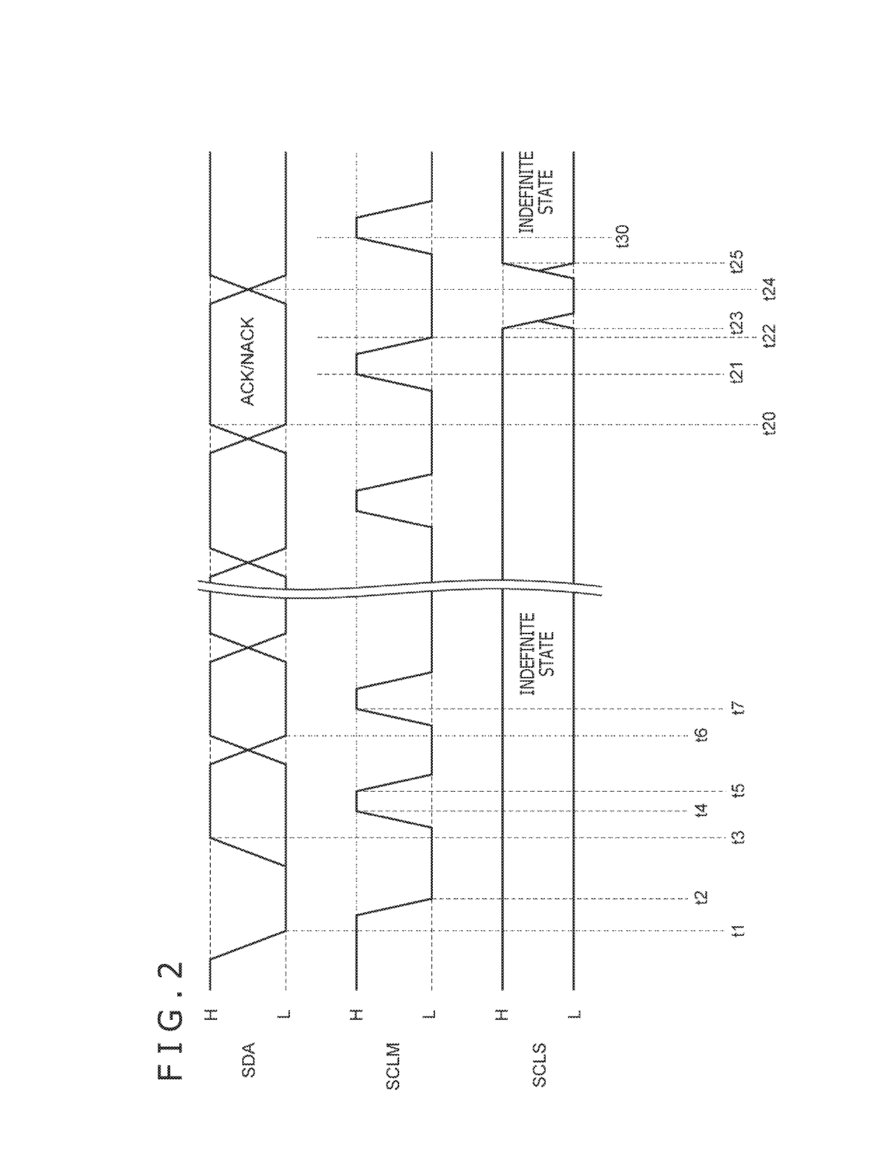

Here, with reference to FIG. 2, the operation of the electronic apparatus 1A will be described. FIG. 2 is a timing chart illustrating an example of transitions of the logic states of the respective signals in the electronic apparatus 1A according to the first embodiment. In FIG. 2, it is assumed that the I3C device 10 is transmitting the data signal SDA to the data bus W_DATA. In addition, in FIG. 2, it is assumed that the I3C device 10 is transmitting the clock SCLM to the clock bus W_CLK. Also, in FIG. 2, it is assumed that only one of the plurality of I2C devices 20 transmits the clock SCLS to the clock bus W_CLK. Further, “H” on the vertical axis in FIG. 2 indicates the “high state” of the logic state. Moreover, “L” on the vertical axis in FIG. 2 indicates the “low state” of the logic state.

At time t1, the I3C device 10 makes a transition of the logic state of the data signal SDA from the “high state “ to the “low state.” At the time t1, the I3C device 10 maintains the logic state of the clock SCLM at the “high state.” As a result, the I3C device 10 transmits a start condition for starting communication according to the I3C communication specification to the I2C device 20 via the data bus W_DATA and the clock bus W_CLK. The start condition is a state where the state in which the logic states of both the data signal SDA and the clock SCLM are the “high states” has made a transition to the state in which the logic state of the data signal SDA is the “low state.” At the time t1, the I2C device 20 maintains a state in which the output of the clock SCLS is stopped. That is, at the time t1, the logic state of the clock SCLS is an “indefinite state.”

At time t2, which is later than the time t1, the I3C device 10 makes a transition of the logic state of the clock SCLM from the “high state “ to the “low state.” At time t3, which is later than the time t2, the I3C device 10 makes a transition of the logic state of the data signal SDA to the logic state of data to be transmitted. At time t4, which is later than the time t3, the I3C device 10 makes a transition of the logic state of the clock SCLM from the “low state” to the “high state.” As a result, the I3C device 10 transmits the data indicated by the data signal SDA to the I2C device 20 via the data bus W_DATA.

At time t5, which is later than the time t4, the I3C device 10 makes a transition of the logic state of the clock SCLM from the “high state “ to the “low state.” At time t6, which is later than the time t5, the I3C device 10 makes a transition of the logic state of the data signal SDA to the logic state of data to be transmitted next after the data transmitted at the time t3. At time t7, which is later than the time t6, the I3C device 10 makes a transition of the logic state of the clock SCLM from the “low state” to the “high state.” Thereafter, the I3C device 10 performs similar operations to those performed from the time t5 to the time t7 and sequentially transmits data to the I2C device 20.

At time t20, which is later than the time t7, the I2C device 20 makes a transition of the logic state of the data signal SDA to a logic state indicating an acknowledgement (ACK) or a logic state indicating a negative acknowledgement (NACK). To be specific, when the I2C device 20 has normally been able to receive the data transmitted from the I3C device 10 between the time t1 and the time t20, the I2C device 20 makes a transition of the logic state of the data signal SDA to the logic state indicating an ACK. On the other hand, when the I2C device 20 has not normally been able to receive the data transmitted from the I3C device 10 between the time t1 and the time t20, the I2C device 20 makes a transition of the logic state of the data signal SDA to the logic state indicating a NACK. The logic state indicating an ACK is the “low state,” for example. The logic state indicating a NACK is a logic state different from the logic state indicating an ACK, such as the “high state.”

At time t21, which is later than the time t20, the I3C device 10 makes a transition of the logic state of the clock SCLM from the “low state” to the “high state.” As a result, the I3C device 10 receives, via the data bus W_DATA, information regarding the response status of the I2C device 20 which is indicated by the data signal SDA. At time t22, which is later than the time t21, the I3C device 10 makes a transition of the logic state of the clock SCLM from the “high state” to the “low state.”

At time t23, which is later than the time t22, the I2C device 20 starts the clock stretching operation. Specifically, the I2C device 20 starts outputting the clock SCLS such that its logic state becomes the “low state.” As a result, at the time t22, the clock bus W_CLK propagates the clock SCL whose logic state is the “low state.” At the time t22, the propagation of the clock SCL to the I3C device 10 is blocked by the blocking device 30A, so that the clock SCL whose logic state is the “low state” is not input to the clock terminal CK of the I3C device 10.

At time t24, which is later than the time t23, the I2C device 20 stops transmitting the logic state indicating an ACK or the logic state indicating a NACK. At the time t24, the I3C device 10 makes a transition of the logic state of the data signal SDA to the logic state of data to be subsequently transmitted.

At time t25, which is later than the time t24, the I2C device 20 ends the clock stretching operation. Specifically, the I2C device 20 stops outputting the clock SCLS. As a result, at the time t25, the logic state of the clock SCLS makes a transition from the “low state” to the “indefinite state.” Note that, at the time t25, the logic state of the clock SCL propagating on the clock bus W_CLK becomes the “low state” because the I3C device 10 outputs the clock SCLM whose logic state is the “low state.” In addition, after starting the clock stretching operation, the I2C device 20 operates to end the clock stretching operation before the I3C device 10 makes a transition of the logic state of the clock SCLM from the “low state” to the “high state” to transmit the next data.

At time t30, which is later than the time t25, the I3C device 10 makes a transition of the logic state of the clock SCLM from the “low state” to the “high state.” As a result, the I3C device 10 transmits the data indicated by the data signal SDA to the I2C device 20 via the data bus W_DATA.

### Effects

As described above, in the first embodiment, the electronic apparatus 1A includes the I3C device 10 (primary device), the I2C devices 20 (secondary devices), the clock bus W_CLK, and the blocking device 30A. The I3C device 10 operates according to the I3C communication specification. Each of the I2C devices 20 operates according to the I2C communication specification but is not compliant with the I3C communication specification. The clock bus W_CLK is connected to the I3C device 10 and the I2C devices 20. The blocking device 30A is connected to the clock bus W_CLK, and blocks the input of the clock SCLS to the I3C device 10 when the clock SCLS transmitted from the I2C device 20 toward the clock bus W_CLK is in a predetermined logic state. If the blocking device 30A is not provided, the clock SCLS in a predetermined logic state (here, the “low state”) will be transmitted from the I2C device 20 to the clock bus W_CLK, and the predetermined logic state will be input to the I3C device 10, causing malfunction. In contrast, the electronic apparatus 1A is provided with the blocking device 30A, which blocks the input of a signal of a predetermined logic state to the I3C device 10. Therefore, the electronic apparatus 1A can perform communication in a state where the I2C device 20 of a non-I3C-compliant type is connected to the bus for the I3C device 10.

Further, in the first embodiment, the blocking device 30A is the diode DI. Moreover, the blocking device 30A has the cathode terminal connected to the clock terminal CK of the I3C device 10 and the anode terminal connected to the clock bus W_CLK. This makes it possible to configure the blocking device 30A simply with a small number of components in the electronic apparatus 1A. Therefore, the electronic apparatus 1A can perform communication at low cost in a state where the non-I3C-compliant I2C device 20 is connected to the bus for the I3C device 10.

In addition, in the first embodiment, the I2C device 20 performs the clock stretching operation defined in the I2C communication specification and ends the clock stretching operation before the logic state of the clock SCLM becomes the “high state.” If the blocking device 30A is not provided, the clock stretching operation (here, input of the clock SCL whose logic state is the “low state”) will not be allowed to be performed on the I3C device 10. In contrast, as long as the electronic apparatus 1A ends the clock stretching operation before the logic state of the clock SCLM becomes the “high state” based on a drive cycle, the electronic apparatus 1A can operate normally by the I2C device 20 receiving the clock SCL whose logic state is the “high state.” Accordingly, the electronic apparatus 1A can perform communication with the non-I3C-compliant I2C device 20 connected to the bus for the I3C device 10 while keeping the clock stretching operation by the I2C device 20 enabled. Moreover, the I3C communication specification defines, as standard values that should be met, a drive frequency (the inverse of the drive cycle) and the minimum value of the period during which the logic state of the clock SCLM is in the “high state.” The electronic apparatus 1A can relax the upper time limit for which the clock stretching operation can be performed by the I2C device 20, by an amount of time obtained by subtracting the minimum value of the period during which the logic state of the clock SCLM is the “high state” from the drive cycle that conforms to the I3C communication specification.

### Second Embodiment

Next, the second embodiment will be described.

### Configuration

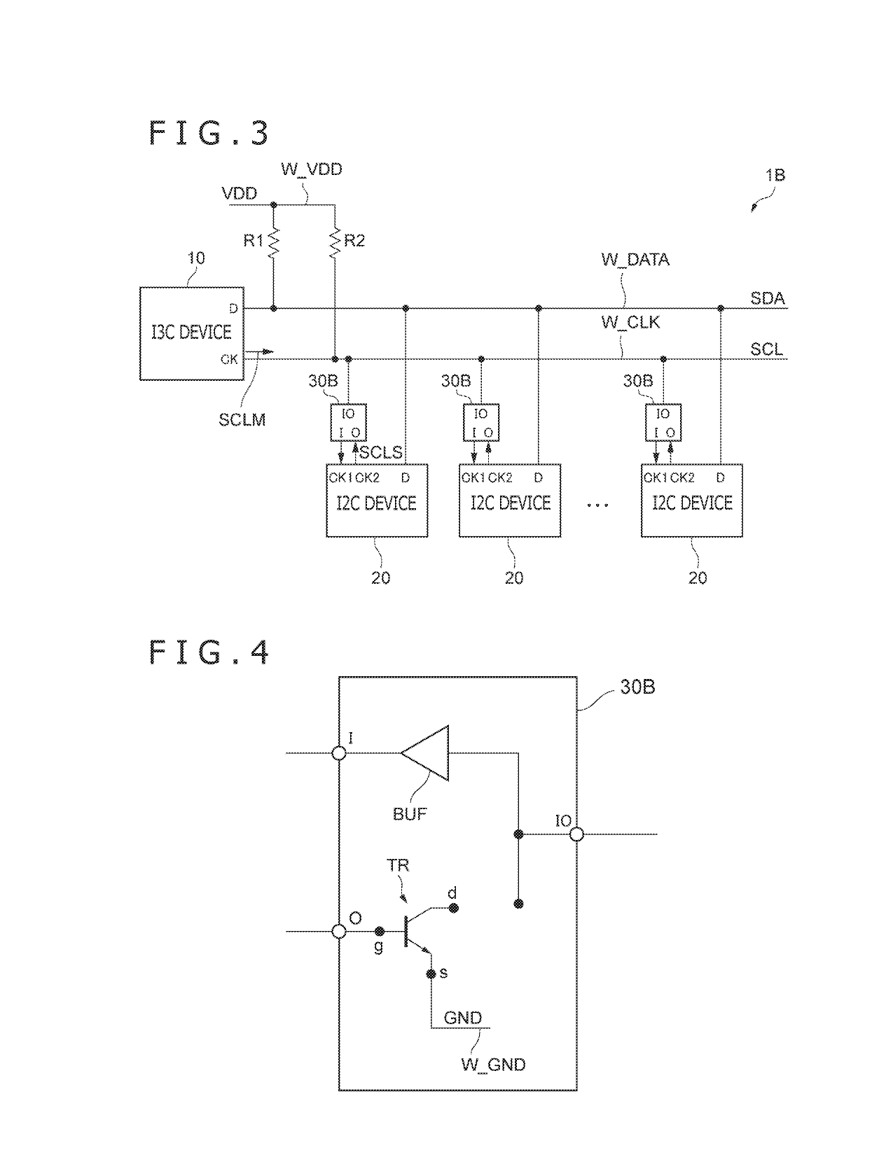

FIG. 3 is a diagram illustrating an example of a circuit configuration of an electronic apparatus 1B according to the second embodiment. As illustrated in FIG. 3, the electronic apparatus 1B according to the second embodiment includes a plurality of blocking devices 30B instead of the blocking device 30A of the electronic apparatus 1A according to the first embodiment. Each of the blocking devices 30B is provided for a corresponding one of the I2C devices 20. Further, in the second embodiment, it is assumed that each of the I2C devices 20 has an input clock terminal CK1 that functions as an input terminal of a clock conforming to the I2C communication specification, and an output clock terminal CK2 that functions as an output terminal of a clock conforming to the I2C communication specification.

The blocking device 30B is an interface conforming to a general purpose input output (GPIO), for example. The blocking device 30B connects the clock bus W_CLK and a corresponding one of the I2C devices 20 to each other. To be specific, the blocking device 30B has an output terminal IO connected to the clock bus W_CLK, an input terminal I connected to the input clock terminal CK1 of the corresponding I2C device 20, and an input terminal O connected to the output clock terminal CK2 of the corresponding I2C device 20.

The blocking device 30B receives, at the output terminal IO, the clock SCLM transmitted from the I3C device 10 via the clock bus W_CLK. The blocking device 30B transmits the received clock SCLM from the input terminal I to the corresponding I2C device 20. Further, the blocking device 30B receives, at the input terminal O, the clock SCLS transmitted thereto from the corresponding I2C device 20. The blocking device 30B blocks the input of the received clock SCLS to the clock bus W_CLK. That is, the blocking device 30B transmits a signal from the clock bus W_CLK to the corresponding I2C device 20 but blocks a signal from the corresponding I2C device 20 to the clock bus W_CLK, preventing the signal from being transmitted.

A specific circuit configuration of the blocking device 30B will be described with reference to FIG. 4. FIG. 4 is a diagram illustrating an example of a circuit configuration of the blocking device 30B according to the second embodiment. As illustrated in FIG. 4, the blocking device 30B includes a buffer circuit BUF and a transistor TR, for example.

The buffer circuit BUF is a buffer circuit including a metal-oxide-semiconductor field-effect transistor (MOS-FET), for example. The buffer circuit BUF applies signal enhancement to a signal input to an input terminal thereof while maintaining the logic of the signal, and outputs the signal subjected to the signal enhancement from an output terminal thereof. The buffer circuit BUF has the input terminal connected to the output terminal IO of the blocking device 30B and the output terminal connected to the input terminal I of the blocking device 30B.

The transistor TR is an N-type MOS-FET, for example. The transistor TR has a gate terminal g connected to the input terminal O of the blocking device 30B, a source terminal s connected to a reference line W_GND having a potential of a ground potential GND, and a drain terminal d connected to nothing and being in an electrically floating state. When the state of a signal input to the gate terminal g is the “high state,” the transistor TR draws out charge from the drain terminal d to the source terminal s. On the other hand, when the state of the signal input to the gate terminal g is the “low state,” the transistor TR stops drawing out charge.

When a signal is input to the output terminal IO, the blocking device 30B configured as described above transmits the signal from the input terminal I via the buffer circuit BUF. In contrast, when a signal is input through the input terminal O, the blocking device 30B blocks the output of the signal regardless of the logic state of the signal because the drain terminal d of the transistor TR is not connected to anything. In other words, the blocking device 30B blocks the output of the signal from the output terminal IO no matter what the logic state of the signal input to the input terminal O may be.

### Effects

As described above, in the second embodiment, the blocking devices 30B are input/output circuits provided between the clock bus W_CLK and the I2C devices 20 (secondary devices). In addition, each of the blocking devices 30B inputs, to the I2C device 20, the clock SCLM transmitted thereto from the I3C device 10 (primary device) via the clock bus W_CLK. Moreover, the blocking device 30B blocks the input to the clock bus W_CLK when the clock SCLS transmitted from the I2C device 20 to the blocking device 30B is in a predetermined logic state. Note that, in the second embodiment, the predetermined logic state includes all logic states. That is, the blocking device 30B blocks the input, to the clock bus W_CLK, of the clock SCLS transmitted from the I2C device 20 to the blocking device 30B. Accordingly, in the electronic apparatus 1B, since the blocking device 30B is the input/output circuit, there is no need to provide components such as the diode DI on the clock bus W_CLK. Therefore, the electronic apparatus 1B can perform communication at an even lower cost with the I2C device 20 of a non-I3C-compliant type connected to the bus for the I3C device 10.

### Modifications

It is to be noted that the present disclosure is not limited to the above embodiments. In other words, if a person skilled in the art makes appropriate design modifications to the above-described embodiments, such modifications are also included within the scope of the present disclosure as long as they have the features of the present disclosure. Further, elements of the above-described embodiments and modification examples described below can be combined to the extent technically possible, and such combinations are also included in the scope of the present disclosure as long as the combinations include the features of the present disclosure.

For example, in the first embodiment, the blocking device 30A is provided between the I3C device 10 and the clock bus W_CLK, but the configuration is not limited to this. For example, each of the blocking devices 30A may be provided between the clock bus W_CLK and a corresponding one of the plurality of I2C devices 20. To be specific, the blocking device 30A may be provided for each I2C device 20 such that the anode terminal of the diode DI is connected to the clock terminal CK of the I2C device 20 and the cathode terminal of the diode DI is connected to the clock bus W_CLK.

According to this configuration, the electronic apparatus 1A does not include the blocking device 30A between the I3C device 10 and the clock bus W_CLK, so that the electrical influence of the blocking device 30A on the I3C device 10 is reduced. Therefore, the electronic apparatus 1A can perform communication with the I2C device 20 of a non-I3C-compliant type connected to the bus for the I3C device 10 while maintaining the performance of the electrical characteristics on the clock bus W_CLK.

Further, the electronic apparatus 1A may include, in a mixed manner, the blocking devices 30A provided between the I2C devices 20 and the clock bus W_CLK and the blocking devices 30B provided between the I2C devices 20 and the clock bus W_CLK as described in the second embodiment. Here, in the configuration in which each of the blocking devices 30A are provided between the I2C device 20 and the clock bus W_CLK, the anode terminal of the diode DI is connected to the clock terminal CK of the I2C device 20, and the cathode terminal of the diode DI is connected to the clock bus W_CLK.

According to this configuration, the electronic apparatus 1A includes the blocking devices 30A and the blocking devices 30B in a mixed manner. Therefore, even when the I2C devices 20 are connected to the clock bus W_CLK in various ways, the electronic apparatus 1A can communicate in a state where the I2C devices 20 of a non-I3C-compliant type are connected to the bus for the I3C device 10.

In addition, in the second embodiment, the blocking device 30B is an interface conforming to a GPIO, but is not limited to this. The blocking device 30B may be any circuit as long as it transmits the clock SCL propagating on the clock bus W_CLK to the I2C device 20 and blocks the clock SCLS transmitted from the I2C device 20 to the clock bus W_CLK.

According to this configuration, the electronic apparatus 1B can use various types of blocking devices 30B, and can therefore communicate in a state where the I2C devices 20 of various interfaces that are not compliant with I3C are connected to the bus for the I3C device 10.

1. An electronic apparatus comprising:
a primary device that operates according to a second inter-integrated circuit communication specification;
a secondary device that operates according to an inter-integrated circuit communication specification but is not compliant with the second inter-integrated circuit communication specification;
a clock bus connected to the primary device and the secondary device; and
a blocking device that is connected to the clock bus and blocks, when a clock transmitted from the secondary device toward the clock bus is in a predetermined logic state, input of the clock to the primary device.

2. The electronic apparatus according to claim 1, wherein
the blocking device is a diode and has a cathode terminal connected to a clock terminal of the primary device and an anode terminal connected to the clock bus.

3. The electronic apparatus according to claim 1, wherein
the predetermined logic state includes all logic states, and
the blocking device is an input/output circuit provided between the clock bus and the secondary device and is configured to input, to the secondary device, a clock transmitted from the primary device to the blocking device via the clock bus but block input, to the clock bus, of a clock transmitted from the secondary device to the blocking device.

4. The electronic apparatus according to claim 2, wherein
the secondary device performs a clock stretching operation defined in the inter-integrated circuit communication specification and ends the clock stretching operation before a logic state of a clock transmitted from the primary device toward the clock bus becomes a high state.
